(19) United States
(12) Patent Application Publication
(10) Pub. No.: US 2010/0027214 A1
(43) Pub. Date: Feb. 4, 2010

(54) MOTHERBOARD MODULE ARRAY

(75) Inventors: Jian-Feng Wu, Shanghai City (CN); Shou-Jen Yang, Taipei City (TW)

Correspondence Address: J C PATENTS, 4 VENTURE, SUITE 250, IRVINE, CA, 92618, US

(73) Assignee: Inventec Corporation, Taipei City (TW)

(21) Appl. No.: 12/331,712

(22) Filed: Dec. 10, 2008

(30) Foreign Application Priority Data
Jul. 31, 2008 (CN) 200810129611.0

(51) Int. Cl. H05K 5/00; H05K 7/20

(52) U.S. Cl. 361/679.47; 361/679.02

(57) ABSTRACT

A motherboard module array suitable for being assembled to a chassis of a server is provided. The chassis includes a bottom plate, two sidewalls, a front plate, and a rear plate opposite to the front plate. The motherboard module array includes at least one group of dividing plates and a plurality of motherboard modules. The dividing plates are arranged inside the chassis and in parallel to the two sidewalls and have at least one group of supporting rails extending inwards. Each of the motherboard modules includes a motherboard which has a plurality of components and an extractable tray which supports the motherboard, wherein the extractable tray is disposed on the supporting rails and the extractable tray is suitable for being pulled out from the chassis.

### CROSS-REFERENCE TO RELATED APPLICATION

This application claims the priority benefit of China application serial no. 200810129611.0, filed on Jul. 31, 2008. The entirety of the above-mentioned patent application is hereby incorporated by reference herein and made a part of specification.

### BACKGROUND OF THE INVENTION

1. Field of the Invention

The present invention relates to a motherboard module array and particularly to a motherboard module array applicable to a server.

2. Description of Related Art

A server is the core which serves all the computers in a network system and has the functions of providing network users discs, printing service, and so forth. Also, the server allows the users to share the resources in the network. The basic frame of the server is approximately the same as that of an ordinary personal computer and comprises a CPU, a memory, and I/O equipment, which are connected by a bus inside. Through north bridge chips, the CPU and the memory are connected, and through south bridge chips, the CPU and the I/O equipment are connected. Based on the structure of a chassis, the development of the server may be roughly divided into three phases: developing from the early tower chassis to the rack mountable chassis which focuses on compact property, and then to the blade server which focuses on high-frequency calculation.

The rack mountable server is given as an example here. The rack mountable server is a server which has appearance of standard design and used together with the chassis. In other words, the rack mountable server is a tower server having superior design, and its purpose is to reduce the space occupied in the server as much as possible. A great deal of network equipment adopts the rack mountable structure, which is mostly flat type, like drawers. The aforesaid network equipments are, for example, exchangers, routers, and hardware firewalls. The rack mountable server is 19 inches wide, and the height thereof is measured by the unit, U (1U=1.75 inches=44.45 millimeters). Generally speaking, the server is classified into 1U, 2U, 3U, 4U, 5U, and 7U types.

The size of the chassis is also regulated by industrial standards, generally from 22U to 42U. Detachable sliding trays may be disposed in the chassis based on the height (U) of the chassis. The user may flexibly adjust the height, according to the level of the server, for storing network equipment, such as servers, hubs, and disc array cabinets. After the server is placed, all the I/O wires thereof may be led out from the rear of the chassis and organized in the wire trenches of the chassis (all the interfaces of the rack mountable server are also located at the rear). Number labels are commonly used to facilitate management.

Generally speaking, the rack mountable server is designed to have one single motherboard inside, and the single motherboard is usually fixed on the chassis. When the motherboard fails, it is inconvenient for the user to disassemble and replace the motherboard, which causes trouble in maintenance. In addition, when parts of the components on the motherboard fail, it is still necessary to replace the whole motherboard, which puts the whole rack mountable server in shutdown status. Consequently, the rack mountable server cannot remain in normal operation for a long period of time.

### SUMMARY OF THE INVENTION

The present invention provides a motherboard module array including a plurality of motherboard modules, and each of the motherboard modules may be respectively maintained and repaired. In addition, a chassis may include a plurality of motherboard modules, so as to increase the utilization of the space in the chassis.

The present invention provides a motherboard module array suitable for being assembled to a chassis of a server. The chassis includes a bottom plate, two sidewalls, a front plate, and a rear plate opposite to the front plate. The motherboard module array includes at least a group of dividing plates and a plurality of motherboard modules. The dividing plates are disposed inside the chassis and in parallel to the two sidewalls and have at least a group of supporting rails extending inwards. Each of the motherboard modules includes a motherboard which has a plurality of components and an extractable tray which supports the motherboard, wherein the extractable tray is disposed on the supporting rails and is suitable for being pulled out from the chassis.

According to one embodiment of the present invention, the dividing plates include a first dividing plate and a second dividing plate located in the chassis. The second dividing plate is substantially parallel to the first dividing plate, wherein a distance is maintained between the first dividing plate and the second dividing plate.

According to one embodiment of the present invention, the supporting rails include a first supporting rail and a second supporting rail. The first supporting rail extends from the first dividing plate towards the second dividing plate, and the second supporting rail extends from the second dividing plate towards the first dividing plate.

According to one embodiment of the present invention, the first supporting rail and the second supporting rail are arranged on the same plane.

According to one embodiment of the present invention, the aforesaid components include at least one heat sink, at least one heat dissipation fan, at least one CPU, at least one control chip, at least one memory, and at least one data registering/outputting port.

According to one embodiment of the present invention, the extractable tray includes a supporting bottom plate and a rear panel. The supporting bottom plate is adapted for supporting the motherboard. The rear panel is connected with the supporting bottom plate and extends upwards from an edge of the supporting bottom plate.

According to one embodiment of the present invention, the rear panel has a plurality of holes.

According to one embodiment of the present invention, the extractable tray is suitable for being pulled out from the chassis at a side where the rear panel is located.

According to one embodiment of the present invention, the supporting bottom plate is parallel to the bottom plate of the chassis of the server.

According to one embodiment of the present invention, the rear panel and the rear plate of the chassis are arranged on the same plane.

According to one embodiment of the present invention, each of the motherboard modules further comprises an elastic latch connected with the extractable tray, and the dividing plates further comprise a latching hole. The elastic latch is adapted for clasping the latching hole, so as to maintain the motherboard module inside the chassis.

According to one embodiment of the present invention, the motherboard module array further comprises a plurality of groups of dividing plates arranged in sequence and adjacent to each other. The extractable trays are respectively disposed on the supporting rails of the groups of dividing plates, and the extractable trays in the groups of dividing plates are stacked in sequence.

The server of the present invention includes a plurality of motherboard modules which function reciprocally, and each of the motherboard modules is disposed in one extractable tray respectively. Therefore, extractable trays may be separately pulled out from the chassis so as to maintain and repair certain motherboard modules without influencing the operation of the server.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a perspective view of a server according to one embodiment of the present invention.

FIG. 2 and FIG. 3 illustrate perspective views of partial structures of the server in FIG. 1.

### DESCRIPTIONS OF EMBODIMENTS

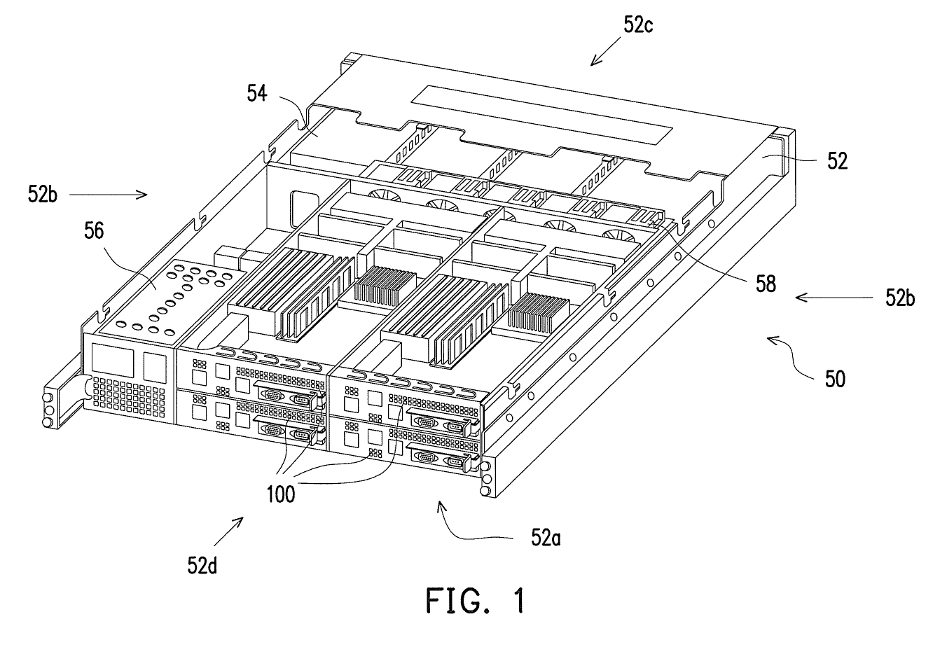

FIG. 1 illustrates a perspective view of a motherboard module array according to one embodiment of the present invention. Referring to FIG. 1, a motherboard module array 100 of this embodiment is suitable for being assembled to a server 50. The server 50 includes a chassis 52, a hard disc array 54, a power supply 56, and a fan module 58. The chassis 52 includes a bottom plate 52a, two sidewalls 52b, a front plate 52c, and a rear plate 52d opposite to the front plate 52c.

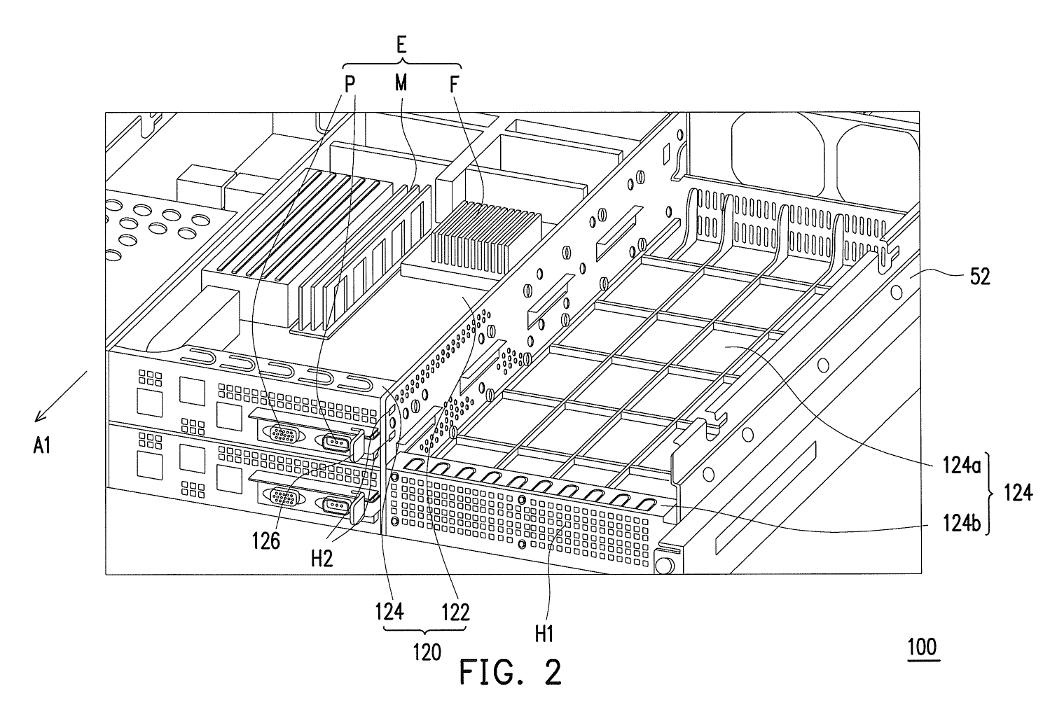

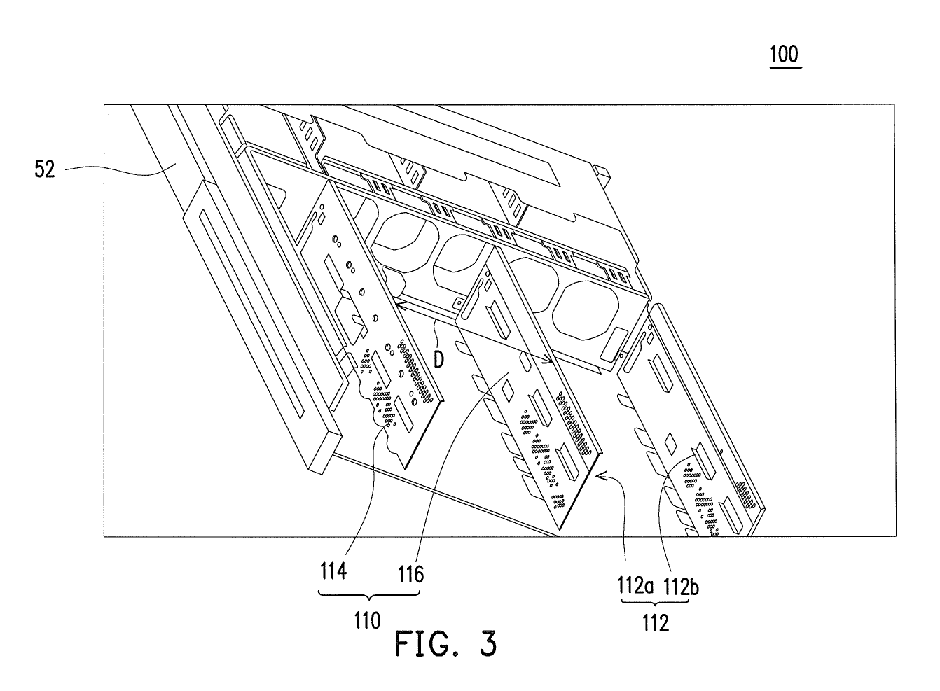

FIG. 2 and FIG. 3 illustrate perspective views of partial structures of the server in FIG. 1. Referring to FIG. 2 and FIG. 3, the motherboard module array 100 includes at least a group of dividing plates 110 (two groups of dividing plates 110 are illustrated as an example in FIG. 2) and a plurality of motherboard modules 120. The dividing plates 110 are disposed inside the chassis 52 and in parallel to the two sidewalls 52b and include at least a group of supporting rails 112 extending inwards. Each of the motherboard modules 120 includes a motherboard 122 which has a plurality of components E and an extractable tray 124 which supports the motherboard 122, wherein the extractable tray 124 is arranged on the supporting rails 112 and is suitable for being pulled out from the chassis 52 in a direction A1. Thereby, the extractable trays 124 may be separately pulled out from the chassis 52 to maintain and repair each motherboard module 120.

In this embodiment, one group of dividing plates 110 is given as an example. However, the present invention is not limited thereto. To be more specific, the motherboard module array 100 may further include other groups of dividing plates, and these groups of dividing plates all have the same structure so as to facilitate mass production. Moreover, these groups of dividing plates may be arranged close to each other, so as to enhance the strength of the structure and increase the flexibility of utilizing the space in the chassis.

Referring to FIG. 3, in this embodiment, the dividing plates 110 include a first dividing plate 114 and a second dividing plate 116 disposed in the chassis 52. The second dividing plate 114 is substantially parallel to the first dividing plate 116, wherein a distance D is maintained between the first dividing plate 114 and the second dividing plate 116. The supporting rails 112 include a first supporting rail 112a and a second supporting rail 112b. The first supporting rail 112a extends from the first dividing plate 114 towards the second dividing plate 116, and the second supporting rail 112b extends from the second dividing plate 116 towards the first dividing plate 114. The first supporting rail 112a and the second supporting rail 112b are arranged on the same plane.

In this embodiment, the first supporting rail 112a and the second supporting rail 112b are given as an example. However, the present invention is not limited thereto. To be more specific, the supporting rails 112 may further include other supporting rails arranged on another plane (different from the plane on which the first supporting rail 112a and the second supporting rail 112b are disposed). In other words, the supporting rails 112 may also include four, six, or more pairs of supporting rails. Thereby, the first dividing plate 114 and the second dividing plate 116 may support more than two motherboard modules 120.

Referring to FIG. 1 and FIG. 2, in this embodiment, the components E include at least one heat sink F, at least one heat dissipation fan (not shown), at least one CPU (not shown), at least one control chip (not shown), at least one memory M, and at least one data registering/outputting port P. The extractable tray 124 includes a supporting bottom plate 124a and a rear panel 124b. The supporting bottom plate 124a is adapted for supporting the motherboard 122 and is parallel to the bottom plate 52a of the chassis 52. The rear panel 124b is connected with the supporting bottom plate 124a and arranged on the same plane as the rear plate 52d. Further, the rear panel 124b extends upwards from an edge of the supporting bottom plate 124a. The rear panel 124b may be one single component or formed by a plurality of sub-components. The data registering/outputting port P is exposed by the rear panel 124b, and the rear panel 124b has a plurality of holes H1, which include holes for heat dissipation and holes for exposing the data registering/outputting port P.

Referring to FIG. 2, in this embodiment, each of the motherboard modules 120 further includes an elastic latch 126 connected with the extractable tray 124, and the dividing plates 110 further include a plurality of latching holes H2. The elastic latch 126 is adapted for clasping the latching hole H2, so as to maintain the motherboard module 120 inside the chassis 52. Certainly, the present invention may also adopt other designs for fixing the extractable tray 124. Therefore, the present invention is not limited to the use of the elastic latch 126 as shown in FIG. 2.

In conclusion, the server of the present invention includes a plurality of motherboard modules which function reciprocally, and each of the motherboard modules is disposed in one individual extractable tray respectively. Consequently, when some motherboard modules fail or need to be maintained, the corresponding extractable trays may be pulled out from the chassis, so as to maintain and repair the motherboard modules without influencing the function of the server. In addition, the chassis may contain a plurality of motherboard modules to increase the utilization of the space in the chassis.

Although the present invention has been disclosed by the above embodiments, they are not intended to limit the present invention. Any person skilled in the art can make modifications and variations without departing from the spirit and scope of the present invention. Therefore, the protection scope of the present invention falls in the appended claims.

What is claimed is:

1. A motherboard module array assembled to a chassis of a server, the chassis comprising a bottom plate, two sidewalls, a front plate, and a rear plate opposite to the front plate, the motherboard module array comprising:
as least a group of dividing plates disposed inside the chassis and in parallel to the two sidewalls and comprising at least a group of supporting rails extending inwards; and
a plurality of motherboard modules, wherein each of the motherboard modules comprises:
a motherboard comprising a plurality of components; and
an extractable tray supporting the motherboard, wherein the extractable tray is disposed on the group of supporting rails and is suitable for being pulled out from the chassis.

2. The motherboard module array as claimed in claim 1, wherein the group of dividing plates comprises:
a first dividing plate assembled to the chassis; and
a second dividing plate assembled to the chassis and substantially parallel to the first dividing plate, wherein a distance is maintained between the first dividing plate and the second dividing plate.

3. The motherboard module array as claimed in claim 2, wherein the group of supporting rails comprises:
a first supporting rail extending from the first dividing plate towards the second dividing plate; and
a second supporting rail extending from the second dividing plate towards the first dividing plate.

4. The motherboard module array as claimed in claim 3, wherein the first supporting rail and the second supporting rail are arranged on a same plane.

5. The motherboard module array as claimed in claim 1, wherein the components comprise at least one heat sink, at least one heat dissipation fan, at least one CPU, at least one control chip, at least one memory, and at least one data registering/outputting port.

6. The motherboard module array as claimed in claim 1, wherein the extractable tray comprises:
a supporting bottom plate for supporting the motherboard; and
a rear panel connected with the supporting bottom plate and extending upwards from an edge of the supporting bottom plate.

7. The motherboard module array as claimed in claim 6, wherein the rear panel has a plurality of holes.

8. The motherboard module array as claimed in claim 6, wherein the extractable tray is suitable for being pulled out from the chassis at a side where the rear panel is located.

9. The motherboard module array as claimed in claim 6, wherein the supporting bottom plate is parallel to the bottom plate of the chassis of the server.

10. The motherboard module array as claimed in claim 6, wherein the rear panel and the rear plate of the chassis are arranged on a same plane.

11. The motherboard module array as claimed in claim 1, wherein each of the motherboard modules further comprises an elastic latch connected with the extractable tray, the group of dividing plates further comprises a latching hole, and the elastic latch is adapted for clasping the latching hole so as to maintain the motherboard module in the chassis.

12. The motherboard module array as claimed in claim 1, further comprising a plurality of groups of dividing plates arranged in sequence and adjacent to each other, wherein the extractable trays are respectively disposed on the supporting rails of the groups of dividing plates, and the extractable trays in the groups of dividing plates are stacked in sequence.
